(19) United States
(12) Patent Application Publication
(10) Pub. No.: US 2014/0202376 A1
(43) Pub. Date: Jul. 24, 2014

(54) METHOD FOR PRODUCING SAPPHIRE SUBSTRATE USED IN LIGHT EMITTING DIODE

(71) Applicant: HON HAI PRECISION INDUSTRY CO., LTD., New Taipei (TW)

(72) Inventors: GA-LANE CHEN, Santa Clara, CA (US); CHUNG-PEI WANG, New Taipei (TW)

(73) Assignee: HON HAI PRECISION INDUSTRY CO., LTD., New Taipei (TW)

(21) Appl. No.: 14/050,362

(22) Filed: Oct. 10, 2013

(30) Foreign Application Priority Data
Jan. 22, 2013 (TW) 102102366

(51) Int. Cl. C30B 15/34

(52) U.S. Cl. CPC C30B 15/34
USPC 117/26

(57) ABSTRACT

In a method, a sapphire raw material is placed into the recess of a mold and melted by heating to infill the recess by capillary action to form a liquid film. A sapphire seed having a specific growing plane is moved to dip the growing plane into the liquid film, thus forming a solid-liquid interface. The sapphire seed is lifted up such that the liquid film is crystallized on the growing surface to form the sapphire substrate. Two surfaces of the sapphire substrate are first coarsely and then finely ground to reduce a thickness of the sapphire substrate. The two surfaces of the sapphire substrate are first coarsely and then finely polished to improve smoothness of the surfaces.

### BACKGROUND

1. Technical Field

The present disclosure relates to sapphire machining and, particularly, to a method for manufacturing a sapphire substrate for use in a light emitting diode.

2. Description of Related Art

Sapphire substrates are widely used in light emitting diodes. At present, sapphire substrates are formed by: growing a sapphire ingot, cutting the sapphire ingot to obtain raw substrates; grinding and polishing each raw substrate to obtain the sapphire substrate. However, the step of growing the sapphire ingot often takes a lot of time. In addition, being limited by cutting precision, a thickness of the raw substrate is often lager than satisfactory, and thus the steps of grinding and polishing take more time to obtain a desired thickness of the sapphire substrate. Therefore, the current method is not efficient.

Therefore, it is desirable to provide a method for producing a sapphire substrate that can overcome the above-mentioned problems.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure.

FIGS. 1-3 are schematic views showing how to manufacture a sapphire substrate, according to an embodiment.

### DETAILED DESCRIPTION

Embodiments of the present disclosure will be described with reference to the drawings.

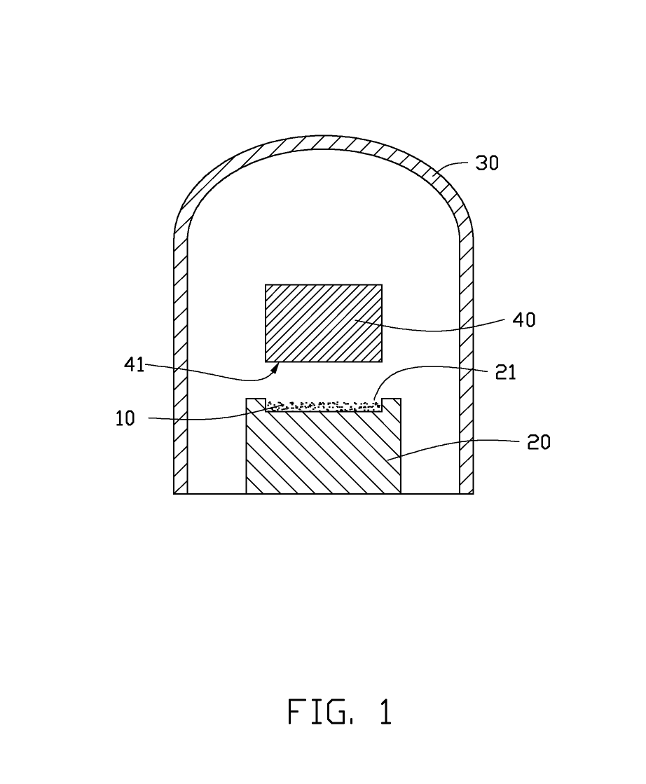

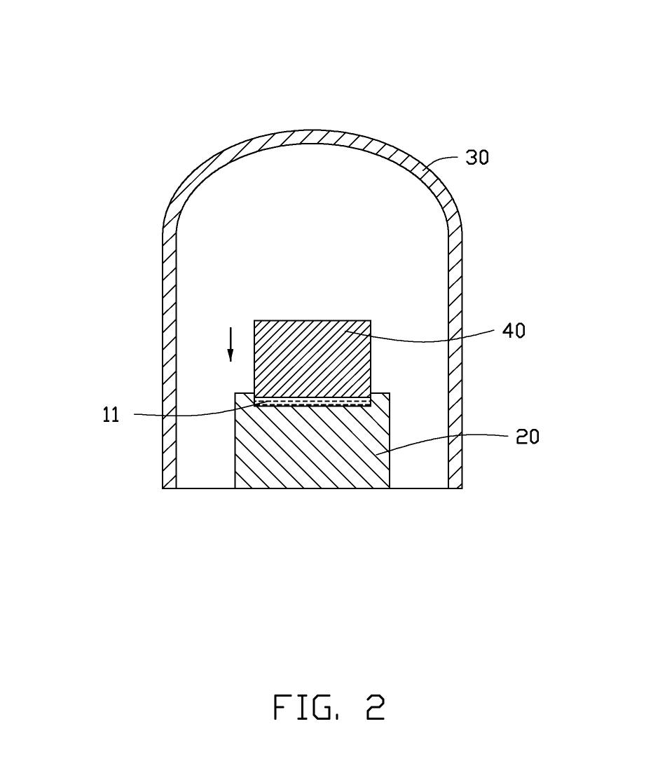

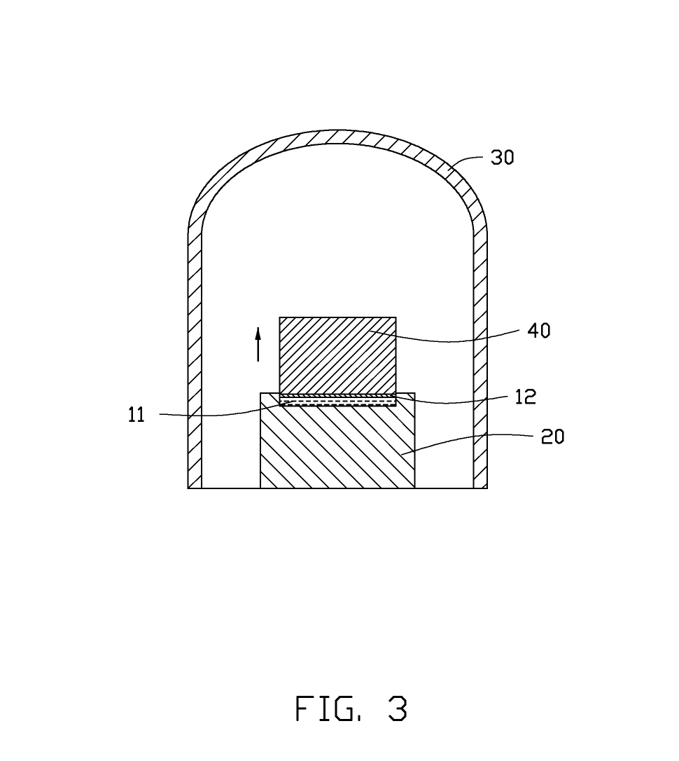

FIGS. 1-3 show how a method for processing a sapphire substrate 12 of an embodiment is performed. The method includes the following steps S01-S08.

In step S01, a mold 20 is provided. The mold 20 defines a film-shaped recess 21.

In step S02, a sapphire raw material 10 is placed in the recess 21 and melted by heating to infill the recess 21 by capillary action to form a liquid film 11.

In step S03, a sapphire seed 40 having a specific growing plane 41 is moved to dip the growing plane 41 into the liquid film 11, thus forming a solid-liquid interface.

In step S04, the sapphire seed 40 is lifted up such that the liquid film 11 is crystallized on the growing surface 41 to form the sapphire substrate 12.

In step S05, two surfaces of the sapphire substrate 12 are coarsely ground to quickly reduce a thickness of the sapphire substrate 12.

In step S06, the two surfaces of the sapphire substrate 12 are finely ground to further reduce the thickness of the sapphire substrate.

In step S07, the two surfaces of the sapphire substrate 12 are coarsely polished to quickly improve smoothness of the surfaces.

In step S08, the two surfaces of the sapphire substrate 12 are finely polished to further improve smoothness of the surfaces.

In comparison, the present method can shorten the processing to about 1/10 of previously known processing times.

The mold 20 is made of iridium, tungsten, molybdenum, or other suitable materials that have a melting point higher than the sapphire raw material 10. The recess 21 should be designed as shallow as possible. As such, the time taken to perform steps S02-04 (i.e., the time for the liquid film 11 to crystallize) is minimized. In addition, an original thickness of the sapphire substrate 20 can be reduced. As such, the time taken to perform steps S02-05 (i.e., the time for grinding and polishing the sapphire substrate 12 to obtain a desired thickness and smoothness) can be minimized. In this embodiment, a depth of the recess 12 is about 3 mm. Corresponding to the depth of the recess 21, the original thickness of the sapphire substrate 12 is about 3 mm.

To perform the steps S02-04, the mold 20 is placed into a furnace 30. The furnace 30 is filled with insert gases, such as nitrogen and argon, and heaters and drivers are employed.

The sapphire raw material 10 is high pure aluminum oxide powder, of which a purity exceeds 99.9%.

In the step S02, the furnace 30 heats the sapphire raw material 10. A heating temperature of the furnace 30 is higher than a melting point of the sapphire raw material 10 but is lower than a melting point of the mold 20. In the embodiment, the heating temperature of the furnace 30 is about 2050 degrees Celsius.

The sapphire seed 40 is made of natural sapphire, and the growing plane 41 is C-plan (associated with a growing axis 0001). The growing plane 41 has a shape and size substantially identical to a shape and size of the recess 21. In the step S03, the sapphire seed 40 is held in the furnace 30 such that the growing plane 41 face the recess 21 directly and is moved towards the recess 21 until the growing plane 41 contacts the liquid film 1.

In the step S01, the sapphire seed 40 is then lifted up after the liquid film 11 contacts the entire growing plane 41. In this embodiment, a lifting speed of the sapphire seed 40 ranges from about 10 mm/h to 25 mm/h. During the lifting, the liquid film 11 crystallizes at the solid-liquid interface. The principle behind the crystallization is similar to the Czochralski method. However, in this step, the sapphire seed 40 is not rotated, as in the Czochralski method, which would thicken the sapphire substrate 12. As such, the lifting speed can be increased and thus the time taken by this step is minimized. In this embodiment, only one day is needed to grow the 3 mm thickness sapphire substrate 12.

In the step S05, diamond grinding wheels having grain size of about 10 um are used to grind the sapphire substrate 12. In this step, only about 20 minutes is all that is needed to reduce the thickness of the sapphire substrate 12 from about 3 mm to about 0.8 mm.

In the step S06, diamond grinding wheels having grain size of about 0.5 um are used to grind the sapphire substrate 12. In this step, only about 150 minutes is all that is needed to reduce the thickness of the sapphire substrate 12 from about 0.8 mm to about 0.7 mm.

In the step S07, polish fluid doped with nano-particles, such as nano-sized silicon dioxide particles having a diameter of about 50 nm, is used. In this step, only about 40 minutes is all that is needed to improve the smoothness of the sapphire substrate 12 to about 50 nm. At the same time, the thickness of the sapphire substrate 12 is reduced from about 0.7 mm to about 0.65 mm.

In the step S07, polish fluid doped with nano-particles, such as nano-sized silicon dioxide particles having a diameter of about 20 nm is used. In this step, only about 240 minutes is all that is needed to improve the smoothness of the sapphire substrate 12 to about 20 nm. At the same time, the thickness of the sapphire substrate 12 is reduced from about 0.65 mm to about 0.6 mm.

It will be understood that the above particular embodiments are shown and described by way of illustration only. The principles and the features of the present disclosure may be employed in various and numerous embodiments thereof without departing from the scope of the disclosure. The above-described embodiments illustrate the possible scope of the disclosure but do not restrict the scope of the disclosure.

What is claimed is:

1. A method for processing a sapphire substrate, the method comprising:
providing mold which defines a film-shaped recess;
placing sapphire raw material into the recess;
melting the sapphire raw material by heating to infill the recess by capillary action to form a liquid film;
dipping a specific growing plane of a sapphire seed into the liquid film to form a solid-liquid interface;
lifting the sapphire seed up such that the liquid film is crystallized on the growing surface to form the sapphire substrate;
coarsely grinding two surfaces of the sapphire substrate to quickly reduce a thickness of the sapphire substrate;
finely grinding the two surfaces of the sapphire substrate to further reduce the thickness of the sapphire substrate;
coarsely polishing the two surfaces of the sapphire substrate to quickly improve smoothness of the surfaces; and
finely polishing the two surfaces of the sapphire substrate to further improve the smoothness of the surfaces.

2. The method of claim 1, wherein the sapphire raw material is high pure aluminum oxide powder, and the mold is made of iridium, tungsten, or molybdenum.

3. The method of claim 1, wherein a purity of the sapphire raw material exceeds 99.9%.

4. The method of claim 1, wherein a depth of the recess is about 3 m.

5. The method of claim 1, wherein the sapphire seed is made of natural sapphire and the growing plane is C-plane.

6. The method of claim 1, wherein the growing plane has a shape and size substantially identical to a shape and size of the recess.

7. The method of claim 1, wherein a lifting speed of the sapphire seed ranges from about 10 mm/h to 25 mm/h.

8. The method of claim 7, wherein a lasting time of the lifting is about one day.

9. The method of claim 1, wherein a grain size of the coarsely grinding is about 10 um.

10. The method of claim 9, wherein a lasting time of the coarsely grinding is about 20 minutes.

11. The method of claim 1, wherein a grain size of the finely grinding is about 0.5 um.

12. The method of claim 11, wherein a lasting time of the finely grinding is about 150 minutes.

13. The method of claim 1, wherein a grain size of the coarsely polishing is about 50 nm.

14. The method of claim 13, wherein a lasting time of the coarsely polishing is about 40 minutes.

15. The method of claim 1, wherein a grain size of the finely polishing is about 20 nm.

16. The method of claim 15, wherein a lasting time of the finely polishing is about 240 minutes.
